(19) United States
(12) Patent Application Publication
(10) Pub. No.: US 2012/0140426 A1
(43) Pub. Date: Jun. 7, 2012

(54) PRINTED CIRCUIT BOARD

(75) Inventors: DUEN-YI HO, Tu-Cheng (TW); YUNG-CHIEH CHEN, Tu-Cheng (TW)

(73) Assignee: HON HAI PRECISION INDUSTRY CO., LTD., Tu-Cheng (TW)

(21) Appl. No.: 12/978,599

(22) Filed: Dec. 26, 2010

(30) Foreign Application Priority Data
Dec. 3, 2010 (TW) 99142068

(51) Int. Cl. H05K 7/06

(52) U.S. Cl. 361/760

(57) ABSTRACT

A printed circuit board includes a top layer. A memory controller, a first dual-channel architecture, and a second dual-channel architecture are located on the top layer. A distance between the memory modules of the first dual-channel architecture and the memory controller is equal to a distance between the memory modules of the second dual-channel architecture and the memory controller.

### BACKGROUND

1. Technical Field

The present disclosure relates to a printed circuit board (PCB).

2. Description of Related Art

Referring to FIG. 4, on a conventional PCB 1, a first memory slot 6, a second memory slot 8, and a memory controller 5 are set on a top layer 2. For saving space of the PCB 1, the first memory slot 6 and the second memory slot 8 are set on a side of the memory controller 5. As a result, a distance between the first memory slot 6 and the memory controller 5 is different from a distance between the second memory slot 8 and the memory controller 5. Therefore, the traces between the two memory slots 6, 8 and the memory controller 5 need to be designed at different length and according to different rules, making the design process overly-complex.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of a first embodiment of a printed circuit board.

FIG. 2 is a schematic diagram of a second embodiment of a printed circuit board.

FIG. 3 is a schematic diagram of a third embodiment of a printed circuit board.

FIG. 4 is a schematic diagram of a conventional printed circuit board.

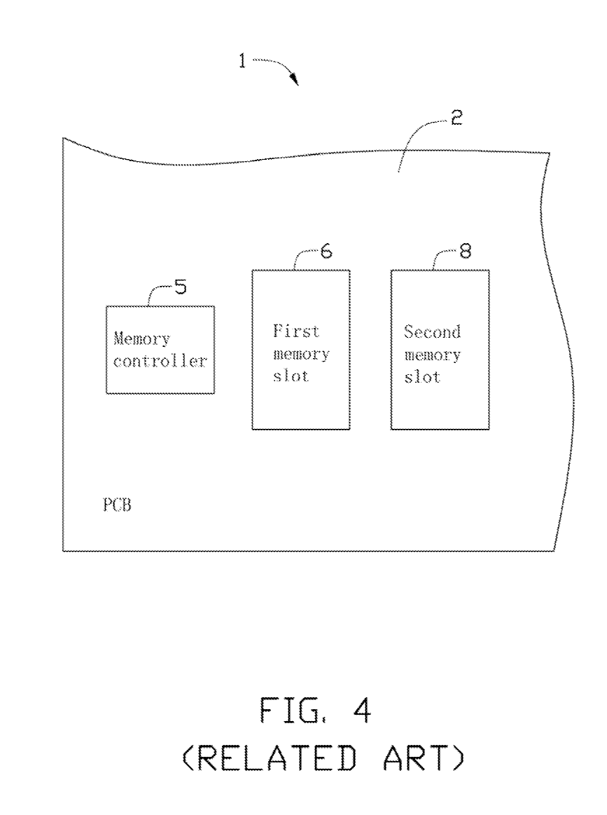

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

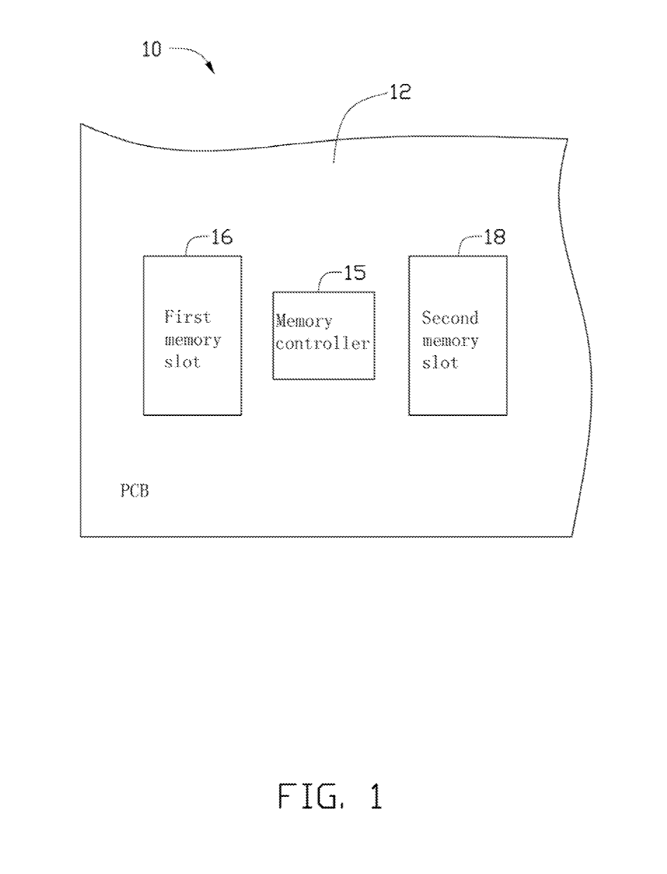

Referring to FIG. 1, a first embodiment of a printed circuit board (PCB) 10 includes a top layer 12 and other layers (not shown). A memory controller 15, a first memory slot 16, and a second memory slot 18 are located on the top layer 12.

The first memory slot 16 and the second memory slot 18 are located at opposite sides of the memory controller 15 respectively. A distance between the first memory slot 16 and the memory controller 15 is equal to a distance between the second memory slot 18 and the memory controller 15. In the embodiment, the distance between the first memory slot 16 and the memory controller 15 is the distance between a center of the first memory slot 16 and a center of the memory controller 15.

The memory controller 15 transmits data between each of two memory cards plugged into the first memory slot 16 and the second memory slot 18 and a central processing unit (CPU). Because the two distances are the same, traces for the first memory slot 16 and the second memory slot 18 can be designed and positioned according to the same rules.

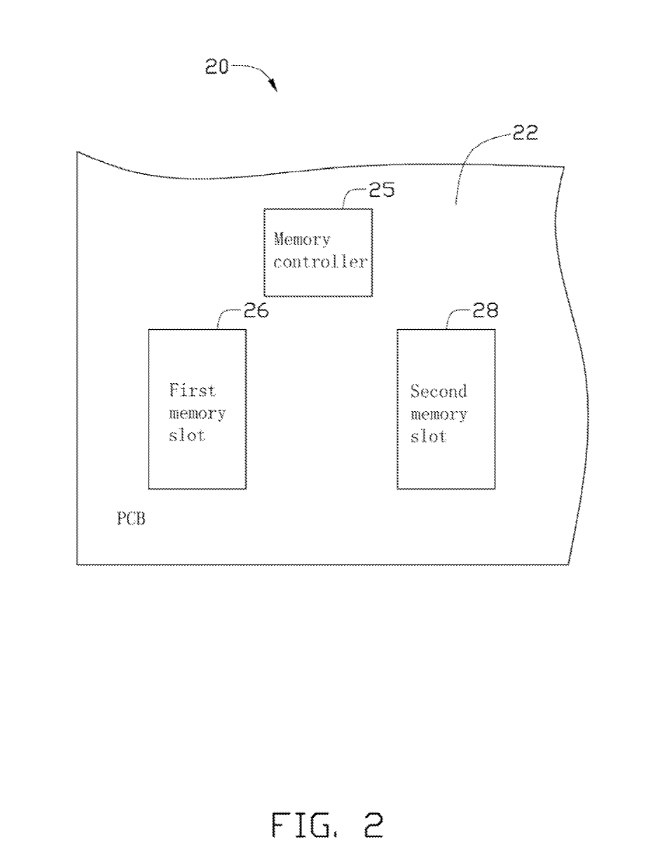

Referring to FIG. 2, a second embodiment of a PCB 20 includes a top layer 22 and other layers (not shown). A memory controller 25, a first memory slot 26, and a second memory slot 28 are located on the top layer 22.

The first memory slot 26 and the second memory slot 28 are located below the memory controller 25 but on opposite sides of the memory controller 25. A distance between the first memory slot 26 and the memory controller 25 is equal to a distance between the second memory slot 28 and the memory controller 25. In the embodiment, the distance between the first memory slot 26 and the memory controller 25 is the distance between a center of the first memory slot 26 and a center of the memory controller 25. Similar to the first embodiment, traces for the first memory 26 and the second memory slot 28 can be designed and positioned according to the same rules. In addition, the two memory slots 26 and 28 may be located above the memory controller 25 but on opposite sides of the memory controller 25.

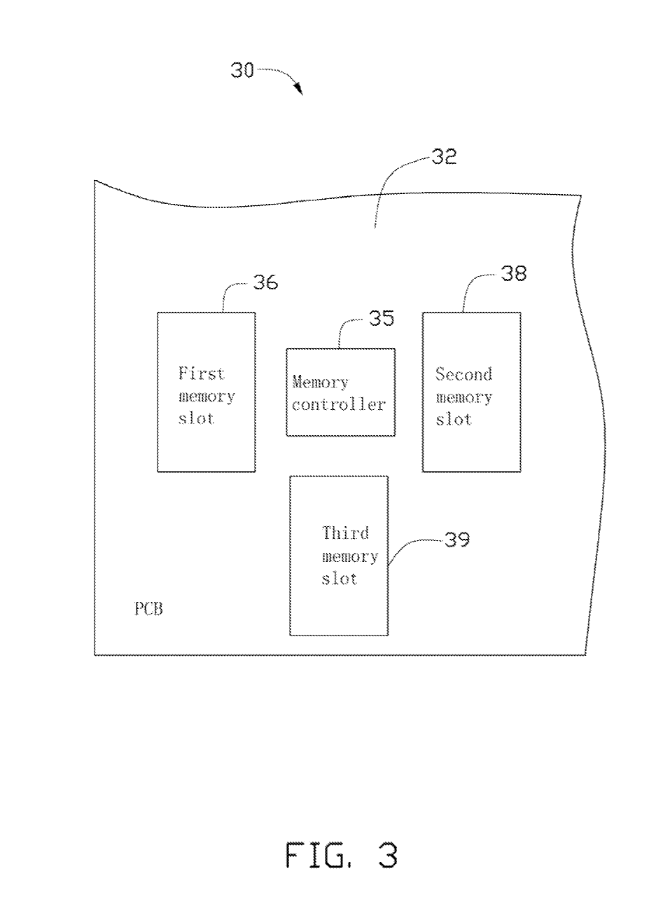

Referring to FIG. 3, a third embodiment of a PCB 30 includes a top layer 32 and other layers (not shown). A memory controller 35, a first memory slot 36, a second memory slot 38, and a third memory slot 39 are located on the top layer 32. The first memory slot 36 and the second memory slot 38 are located on opposite sides of the memory controller 35 and the third memory slot 39 are located directly below the memory controller 35. Similar to the first embodiment and the second embodiment, a distance between the first memory slot 36 and the memory controller 35, a distance between the second memory slot 38 and the memory controller 35, and a distance between the third memory slot 39 and the memory controller 35 are the same.

Moreover, traces for PCBs with more than three memory slots can be designed according to the first to third embodiments. In other words, a distance between each memory slot and the memory controller is the same. In addition, if the two memory slots makes up a dual-channel architecture, the two dual-channel architectures can be designed according to the same rules. In other words, a distance between a center of the memory modules of a first dual-channel architecture and the memory controller is equal to a distance between a center of the memory modules of a second dual-channel architecture and the memory controller. Of course, two memory slots in each dual-channel architecture are designed according to the same rules too.

The foregoing description of the exemplary embodiments of the disclosure has been presented only for the purposes of illustration and description and is not intended to be exhaustive or to limit the disclosure to the precise forms disclosed. Many modifications and variations are possible in light of the above everything. The embodiments were chosen and described in order to explain the principles of the disclosure and their practical application so as to enable others of ordinary skill in the art to utilize the disclosure and various embodiments and with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A printed circuit board comprising a top layer, and a memory controller, a first dual-channel architecture, and a second dual-channel architecture arranged on the top layer, wherein a distance between memory modules of the first dual-channel architecture and the memory controller is equal to a distance between memory modules of the second dual-channel architecture and the memory controller.

2. The printed circuit board of claim 1, wherein the first dual-channel architecture and the second dual-channel architecture are located at opposite sides of the memory controller respectively.

3. The printed circuit board of claim 1, wherein the first dual-channel architecture and the second dual-channel architecture are located below or above the memory controller but on opposite sides of the memory controller.

4. The printed circuit board of claim 1, further comprising a third dual-channel architecture arranged on the top layer, wherein a distance between memory modules of the third dual-channel architecture and the memory controller is equal to the distance between the memory modules of the first dual-channel architecture and the memory controller.

5. A printed circuit board comprising a top layer, and a memory controller, a first memory slot, and a second memory slot arranged on the top layer, wherein a distance between the first memory slot and the memory controller is equal to a distance between the second memory slot and the memory controller.

6. The printed circuit board of claim 5, wherein the first memory slot and the second memory slot are located at opposite sides of the memory controller respectively.

7. The printed circuit board of claim 5, wherein the first memory slot and the second memory slot are located below or above the memory controller but on opposite sides of the memory controller.

8. The printed circuit board of claim 5, further comprising a third memory slot arranged on the top layer, wherein a distance between the third memory slot and the memory controller is equal to the distance between the first memory slot and the memory controller.
